(19) United States
(12) Patent Application Publication
(10) Pub. No.: US 2004/0226601 A1
(43) Pub. Date: Nov. 18, 2004

(54) Photovoltaic/solar safety and marker tape

(76) Inventor: Mark Banister, Tucson, AZ (US)

Correspondence Address: MARK BANISTER, 6550 E. MIRAMAR DR., TUCSON, AZ, 85715, US

(21) Appl. No.: 10/786,279

(22) Filed: Feb. 24, 2004

Related U.S. Application Data
(60) Provisional application No. 60/448,888, filed on Feb. 24, 2003.

(51) Int. Cl. H01L 31/00

(52) U.S. Cl. 136/252; 136/244

(57) ABSTRACT

A self-contained safety marker or hazard marking tape or laminate includes a combination of devices laminated together to produce a thin illuminating and reflective device that is independently powered, capable of being multi colored and can send and receive sensor signals.

### CROSS-REFERENCE TO RELATED APPLICATION

This application claims priority under 35 U.S.C. 119 from U.S. Provisional Patent Application No. 60/448,888 filed Feb. 24, 2003 which is incorporated by reference for all purposes.

### FIELD OF THE INVENTION

The present invention relates to a highly visible, easily deployed hazard and safety marking device that can be easily mounted to many surfaces in temporary or permanent conditions.

### DESCRIPTION OF PRIOR ART

The provision of safety markings or hazard markings has been known in the art for many years. These devices have been somewhat limited to reflectors, reflective tapes, illuminating devices, fluorescent materials and paints.

U.S. Pat. No. 3,971,623 consists of a fixed roadway marker having a shell-like body with a chamber formed therein. The body is at least partially transparent to form a transparent outer wall for the chamber so the interior of the chamber is visible. Either daytime or nighttime marker elements or both may be provided in the chamber.

U.S. Pat. No. 4,340,319 shows a pavement marker for engagement with an underlying roadway for providing a marker visible from an oncoming vehicle on the roadway surface. The pavement marker comprises a lens member of light transmitting synthetic resin, and a rear surface having a reflex reflective means for reflecting light transmitted through a light receiving and refracting portion back to the source.

U.S. Pat. No. 6,382,126 describes a flexible reflective safety, signal and warning patch. The patch is attachable to clothing or an object and includes a plurality of reflective panels in a variety of geometric shapes using reflective, prismatic or fluorescent material

U.S. Pat. No. 5,782,552 consists of a light assembly comprising a LED a rechargeable diode and a solar cell to recharge the capacitor. The solar cell is further utilized as a photosensor to energize the LED at a pre-determined level of light.

U.S. Pat. No. 6,619,831 provides a flexible strip light emitter comprised of LEDs and electrodes covered by a synthetic resin made from strip shaped transparent vinyl and a provision for reflective sheets.

U.S. Pat. No. 6,687,266 describes organic light emitting materials and devices. These devices include an anode, a cathode and an emissive layer disposed between the anode and cathode. Various materials and the colors they emit are discussed along with particle size and the ability for the layers to be transparent.

U.S. Pat. No. 5,469,020 shows active light emitting components are integrated into a thin flexible plastic-wrap like film to provide an exceptionally large continuous display in which the film contains densely distributed light emitting elements addressed by a grid of transparent conductors.

U.S. Pat. No. 6,541,695 consists of methods and materials to produce high efficiency low cost photovoltaic layers in large volume.

U.S. Pat. No. 6,664,898 provides for multiple hazard field marker and components and describes a system comprising of at least one multiple hazard marking device, a deployment vehicle, a communication system, a deployment surface.

Known sensors and circuits are described in several books by Joseph J. Carr, Sensors and Circuits, published by Prentice-Hall, Englewood Cliffs, N.J., 1993, Sensor Circuitry, published by Delmar Publishers, 1997, RF Components and Circuitry, published by Newnes, 2002, Electro-optic Circuitry, published by Delmar Publishers, 1997

### SUMMARY OF THE INVENTION

The purpose of this invention is to provide a compact long lasting, versatile electronic safety and marking device that can provide high visibility. The size, simplicity and durability of the design is believed to be of major significance in providing hazard or safety marking over a wide range of applications.

Furthermore the invention can take advantage of large volume manufacturing processes, such as roll to roll lamination or sheet lamination techniques in order to produce the device in an economic manner.

In its simplest form it can be applied directly from a roll to a roadway, barrier or object to provide a glowing, or flashing indicator of direction, hazard or safety condition. By adding interactive sensing and signaling abilities it can turn itself on or off according to conditions or signal when a person or vehicle is near, thereby conserving energy and the life of the device.

Other uses can be for chemical, biological, location or radiation detection that can be activated remotely to identify and tag an object or area as to the hazard or safety issue and relevant degree of exposure. It is foreseen that the invention could be manufactured as an adhesive backed stick on that could detect and reflect light, Infrared and Radio Frequency signals and illuminate and transmit a hazard or rescue signal.

Additionally the invention could be transparent and applied to surfaces where it would not be easily seen by the human eye. Or applied as a transparent laminate to a window with the non transparent electronics applied or attached to the side of the window for concealment

Further uses could include a plurality of the sensors to form a system interconnected by electric, optic illumination or transmitting and receiving signals,

The invention could also be sewn on to fabric or attached to objects using a removable system such as Velcro or snaps.

### BRIEF DESCRIPTION OF THE DRAWINGS

FIG. 1 is a perspective view of an embodiment showing the laminated layers;

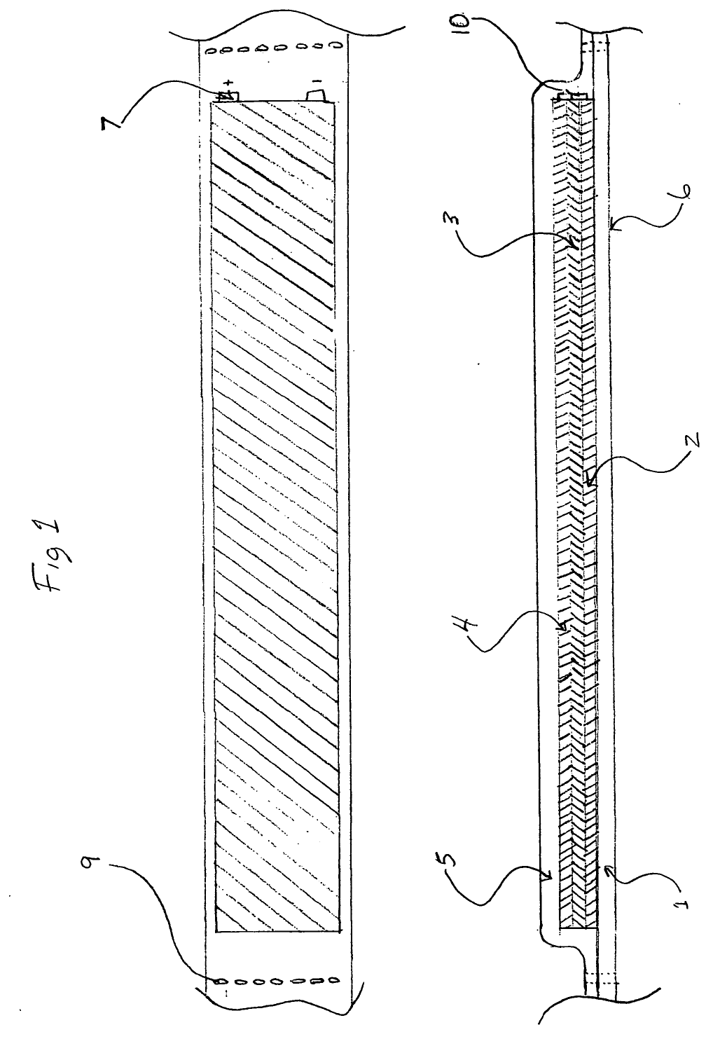

FIG. 2 is a simple schematic of FIG. 1;

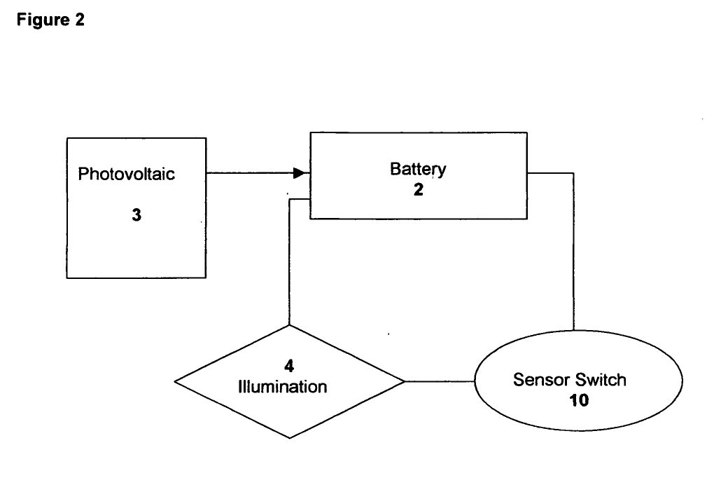

FIG. 3 is a perspective view of an embodiment with multiple illumination, reflection and sensor capabilities as a round adhesive backed stick on; and

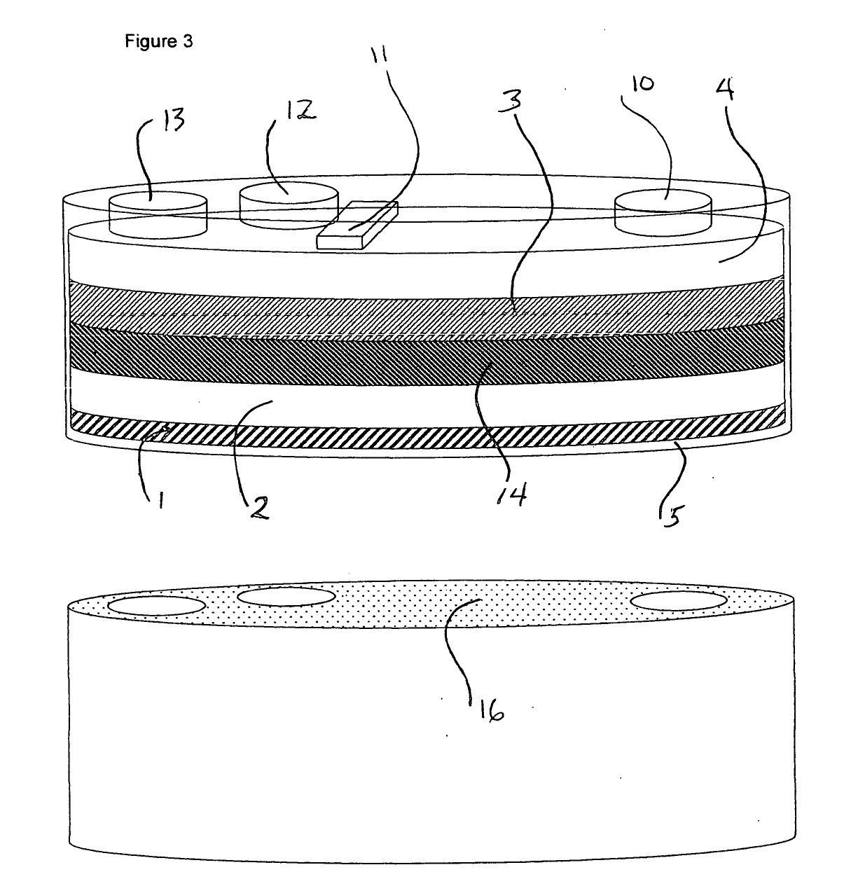

FIG. 4 is a simple schematic of FIG. 3.

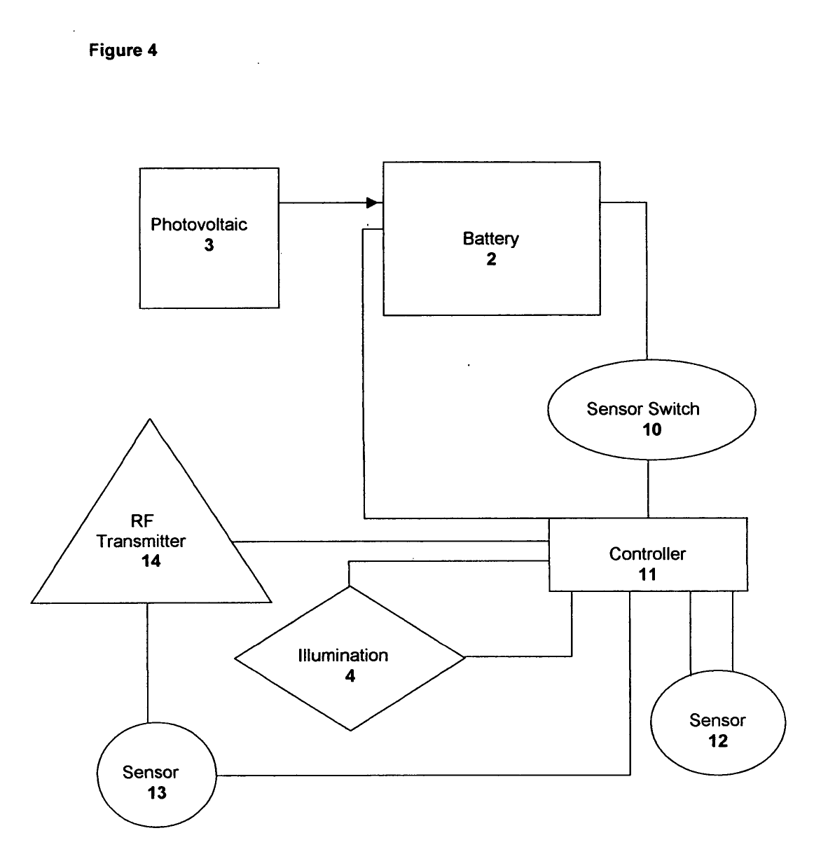

### DETAILED DESCRIPTION OF THE PREFERED EMBODIMENTS

Respective embodiments of the safety and marker tape will be described specifically below. Laminates and lamination techniques vary dependent on materials used in and on the layers. Examples of layer materials are acrylics, polymers and foils. Pressure sensitive adhesives include acrylic based, rubber based and polyester based and are used with various additives such as cross-linking agents and are widely known and readily available commercially through companies like 3M. Additional forms of lamination can include but are not limited to heat, chemical, and light curing.

Starting with a base layer(1) each electrical component is stacked with an insulating, conductive or adhesive layer or combination; then pressure, heat, light or combinations of these are applied per laminating product specifications. The final layer(5) can be a soft embeding material that cures or a spray on coating such as a polymer paint.

The electrical components are readily available through manufacturers such as Mactac Technical Products located in Stow, Ohio, which manufactures RFID Radio Frequency Identification tape(14), currently used for inventory control, retail security, and electronic toll management. Electroluminescent tape(4) is also readily available through Martac.

Photovoltaic(3) and battery(2) thin films are readily available through manufacturers who can produce them to customer size and apply an adhesive. One such company is Global Solar located in Tucson, Ariz. Most of these thin films are produced via vacuum vapor deposition or sputtering producing ultra fine metalic or conductive layers over a thin foil or film. The order and composition of the layers produce the desired electrical properties. The batteries can be stacked if needed to achieve the desired voltage. The battery could also be replaced by a fuel cell although these are not readily available at this time and will most likely be cost prohibitive until they are mass produced.

Currently there is much research being conducted to produce TiO based electric film products due to its organic properties, availability and related costs. TiO based films are available that are transparent and applicable to large volume manufacture, although not as efficient as metal or silicon based photovoltaics. The inexpensive manufacturing and properties of these make them desirable.

Electrical connections in the preferred embodiment would be made during the lamination process with circuitry(14) that is printed, etched or plated on a laminate film or layer that corresponds with the electrode connections for each layer. Silver, platinum and gold conductive films are available in a variety of compositions that can be transparent. This would be readily apparent to any one schooled in the art.

Controler(11) and sensors(12, 13) would be added and electrically connected for desired sensing and signaling properties. These would also if needed be masked before assembly or final sealing layer is applied. Light reflective material(16) such as Scotchlite™ By 3M and colors can be added or printed before or in the sealing layer(5). Laser cutting, etching and molding portions of one or more layers can add other reflective properties. In addition glass or silicon spheres added to a layer or surface can add reflective properties as well. Once the final sealing layer and adhesive backing can be applied the product may be stamped or cut out of a sheet or roll. The product could additionally be left in roll or sheet form with cuts or perforations at or around the product for easy removal or application. This would be readily apparent to anyone schooled in the art. Roll to roll lamination is essentially combining material from one roll with a process to produce a second roll or combine material from one roll with another one or more rolls to produce a subsequent roll.

While the various features of this invention are described and illustrated as a photovoltaic/solar safety and marker tape it is to be understood that the embodiments in the figures and description are merely representative of the myriad of safety and marker tape combinations which can be constructed to accomplish the purpose of this invention and this invention is not to be limited in the scope by the figures presented.

1. A laminated electrical device comprising stacked layers including a substrate, a photovoltaic to produce electricity, a device for storing electricity produced by the photovoltaic, a source of illumination, electrical circuitry for electrically connecting the aforesaid electrical components, and a protective surface.

2. The device as in claim 1 wherein the substrate is rigid.

3. The device as in claim 1 wherein the substrate is flexible.

4. The device as in claim 1 further comprising an adhesive and a removable covering for the adhesive applied to said protective surface or substrate.

5. The device as in claim 1 further comprising an alternative electrical power inlet and outlet connection point in electrical connection with said electrical circuitry.

6. The device as in claim 1 further comprising a thermally conductive layer in contact with said electric components or layers to dissipate heat from said electric components.

7. The device as in claim 1 further comprising one or more sensor switches in electrical connection with said electrical circuitry for turning one or more of said electrical components on and off.

8. The device as in claim 1 further comprising one or more controllers in electrical connection to said electrical components or circuitry to control activation and/or duration of illumination and/or signal.

9. The device as in claim 8 further comprising one or more sensors in electrical connection to said electrical circuitry to provide sensor feedback to the controller.

10. The device as in claim 1 further comprising one or more signal transmitters and receivers in electrical connection to said electrical circuitry.

11. The device as in claim 1 said electrical circuitry prevents electric current drain through said photovoltaic.

12. The device as in claim 1 wherein said device for storing electricity comprises one or more capacitors.

13. The device as in claim 1 wherein said device comprises one or more batteries or fuel cells.

14. The device as in claim 1 wherein one or more of said electrical component layers are transparent.

15. The device as in claim 1 wherein one or more of said non-electrical component layers are transparent.

16. The device as in claim 1 further comprising one or more transparent adhesive layers.

17. The device as in claim 1 wherein the source of illumination emits light in the visible light spectrum, non-visible spectrum or combination of both.

18. The device as in claim 17 wherein the source of illumination comprises one or more light emitting diodes.

19. The device as in claim 17 wherein the source of illumination comprises one or more organic light emitting devices.

20. The device as in claim 17 wherein the source of illumination comprises one or more electroluminescent materials.

21. The device as in claim 17 wherein the source of illumination comprises one or more illuminating chips, preferable a laser, photonic, LED or other miniature light emitting source.

22. The device as in claim 1 further comprising one or more layers of light refractive materials.

23. The device as in claim 1 further comprising one or more layers of light reflective materials.

24. The device as in claim 23 wherein the light reflective material is oriented to reflect in one or more directions.

25. The device as in claim 1 further comprising one or more layers of fluorescent materials.

26. The device as in claim 1 further comprising one or more layers of luminescent materials.

27. The device as in claim 1 further comprising one or more layers of dielectric materials.

28. The device as in claim 1 wherein an exterior surface of the device is smooth.

29. The device as in claim 1 wherein an exterior surface of the device is textured.

30. The device as in claim 1 wherein one or more electrical components are combined in a single layer.

31. The device as in claim 1 comprising a plurality of layers or multiple devices assembled edge to edge.

32. The device as in claim 1 comprising a plurality of layers or multiple devices laminated edge to edge

33. The device as in claim 1 comprising a plurality of devices in electrical, illumination or signal connection.

34. (canceled).

35. (canceled).
